(19) United States
(12) Patent Application Publication
(10) Pub. No.: US 2014/0022834 A1
(43) Pub. Date: Jan. 23, 2014

(54) CREATING UNIQUE IDENTIFICATION FOR AN ARRAY ELEMENT

(71) Applicant: Nitin Jain, San Diego, CA (US)

(72) Inventor: Nitin Jain, San Diego, CA (US)

(73) Assignee: ANOKIWAVE, INC., San Diego, CA (US)

(21) Appl. No.: 13/288,910

(22) Filed: Nov. 3, 2011

Related U.S. Application Data
(60) Provisional application No. 61/409,878, filed on Nov. 3, 2010.

(51) Int. Cl. G11C 8/06

(52) U.S. Cl. CPC G11C 8/06
USPC 365/154

(57) ABSTRACT

A circuit arrangement for assigning identification address to each element of an array of elements of a phased array, or assigning a unique digital word to a isolated circuit. In one embodiment two external resistors are used to provide an analog voltage. That voltage can be converted to digital word and stored in a chip using latches and registers. The stored digital word can then be use as address for the army element used in phased array. Thereby access to the array element can achieved using the address as a header of a digital bit stream.

### CROSS-REFERENCE TO RELATED APPLICATION

This application claims the benefit of provisional patent application Ser. No. 61/409,878, filed 2010 Nov. 3 by the present inventor.

### FEDERALLY SPONSORED RESEARCH

Missile Defense Agency contract HQ0006-10-C-7397

### SEQUENCE LISTING

None

### BACKGROUND

### Prior Art

Modern antennas are designed to focus a radiated beam in a desired direction and suppress the beam in an undesired direction. While this can be achieved by mechanical means such as parabolic antenna or lens, there is a growing tendency to do this electronically because electronic beams can be steered quickly. Electronic beam forming is achieved by providing an array of circuit-elements that are physically spaced and radiate in varied relative phases and amplitudes such that the radiation pattern is reinforced in the desired direction and suppressed in the undesired direction. Such array elements (typically 64×64 elements or more) form a phased array. Each army element needs to be programmed to give the right phase and amplitude, thereby forming the desired beam pattern.

The array elements of phased array have built in memory (in form of buffers, latches or flip-flops) that need to be programmed. The memory in turns programs the array element to provide right phases and amplitudes. A shift register (or memory) for the array elements has a number of stages that are daisy chained in a FIFO (first-in-first-out) manner. The programming is achieved by sending an pre-arranged digital data stream (comprising “1s” and “0s”) though the daisy chain until all of the shift register stages are programmed with their intended values. This approach is highly favored in phased arrays because it avoids extra lines on the phased array's printed circuit board. However, it has a major drawback: it is not possible to address individual array element as they do not have respective unique digital addresses. Thus to program one array element, a long data stream must be supplied to fill up the entire daisy-chained shift register stages for the array. As a result the programming process is very slow.

Besides the phased array elements, there are additional electronic components that need to be programmed. Monolithic Integrated circuits (MICs, also known as chips or silicon ICs) include many circuits formed in a single piece of silicon. Typically MICs can be programmed to provide varying output performance. For example a synthesizer MIC (such as ADF4350 from Analog Devices, Inc., 3 Technology Way, Norwood, Mass. 02062), can generate many different frequencies depending upon a programmed counter value. Usually, an external microcontroller or microprocessor is used to program the counter value to provide the correct frequency. However, as ICs become ubiquitous there is a need to program ICs without the use of the expensive external components such as microcontroller or microprocessor.

Typically phased arrays have large number of elements in the form of Transmit and Receive modules. (T/R modules are also referred as array elements or active elements.) Such modules typically are arranged in an orthogonal or X-Y direction. For example the Terminal High Altitude Air Defense (THAAD) Radar (AN/TPY-2) has 25,000 active elements (see Principles of Modern Radar Vol 1 by M A. Richards, J. A Scheer, W. A Holm, Scitech Publishing Inc., 2010). During the operation of the radar it is highly desirable to access each of the array elements to control its phase and amplitude to form digital-beam steering. This can improve radar performance by improving search/detect, target tracking, and imaging. In addition beam steering and shaping can greatly enhance communication systems as well Such systems include the 60 GHz links demonstrated by SiBeam in 2009-2010 (SiBEAM, Inc., 555 N. Mathilda Ave., Sunnyvale, Calif. 94085).

Unique addressing of the active elements of array elements can be achieved by (1) an Electrically Erasable Programmable Read-Only Memory (EEPROM), and (2) fuses that are burned (opened), thereby to wire or hard-programmed the circuit. Each of these approaches is explained below and has a number of short comings.

In theory an EEPROM would work well as each chip can be programmed with a unique address. Unfortunately, many high frequency IC fabrication processes, such as SBC18HA (process from TowerJazz USA, a subsidiary of Jazz Semiconductor) and IBM's BiCMOS 8HP process (from IBM Systems and Technology Group) do not have an EEPROM option. Very often an EEPROM cell requires extra space, thereby taking up expensive area on the MIC.

Fuses are available as a process option for both SBC 18HA and IBM BiCMOS 8HP processes. Leaving the fuse connected could form a “1” and blowing the fuse a “0”, and by having a number of fuses, a unique address pattern in “1s” and “0s” can be programmed. Unfortunately, the fuses too have a limitation as they need a very high current to be blown. In addition, the fuses can occupy substantial space and are unreliable.

In addition, in big array there is a problem of replacement. When a part fails it needs to be replaced. For a 1024×1024 array few sites fail in a routine manner. These failures are related to mean time between failure statistics and for large arrays such failure becomes statistically more probable. The replacement process for the part can be very tedious and time consuming.

Prior approaches using microcontrollers or microprocessors is expensive, daisy chain programming of the array element is time consuming and inefficient, and EEPROM or fuses for assigning permanent memory states are not universally applicable. Thus we have found that heretofore there has not been any easy way to program the array elements of phased arrays.

### ADVANTAGES

This specification outlines methods and concepts such that a unique digital word can be created by proper choice of external components and used to control a digitally controllable circuit. Accordingly one or more aspects of the present system have the following advantages: A unique address for array element, a chip, circuit, or module is provided and made from an external location by a user-selected inexpensive part. Thus no internal memory or fuses are required to create a unique address for each army element. Since this approach avoids the use of microcontrollers and processors, it is very inexpensive. In a phased array application external resistors can be used to generate local address of the array component. Thus chips can be easily repaired when failure occurs since each chip is uniquely defined. Another advantage is that the address is non-volatile; it remains the same when the device is restarted and does not need to be reprogrammed.

Further advantages of various embodiments and aspects will be apparent from the ensuing description and drawings.

### SUMMARY

The present system relates generally to a circuit that creates a unique digital word useful for providing a unique digital address that can be stored and assigned to each element of a phased array. The assigned address can be used to individually access the array element and control it digitally. Thus, because each element has a unique address, all of the array elements can be connected in parallel to same programming lines without being daisy chained. Each array element can be accessed individually through its unique address.

A unique address is provided for each chip of an array by feeding a voltage from DC voltage supply to an external resistance ladder to create an analog voltage that is fed back into the chip. In the chip, the analog voltage is converted to a digital word using an analog-to-digital converter. The digital word is used by a digitally controllable circuit or active element to determine its state, including but not limited to its digital address.

Alternative, a component is placed outside of a chip. The value of the component creates a unique signature that falls in the range of a multitude of possibilities. Based on the unique signature, a unique bit sequence is selected by the chip as its unique address or state.

In another embodiment, a circuit that controls a digitally controllable component comprises a first circuit means that creates a unique analog signal and a second circuit means that convert the unique analog signal into a unique digital word, which then controls the digitally controllable component.

### DRAWINGS

FIG. 1 is a circuit schematic for creating unique digital word for a array element.

FIG. 2 shows another embodiment using a single unique component.

REFRENCE NUMERALS

| | |
|---|---|
| 100 | A circuit for unique digital word |
| 101 | Bottom series resistor |
| 102 | Top series resistor |
| 103 | Eight bit analog to digital converter |
| 104 | External capacitor for bypassing Vcc |
| 105 | Supply voltage, Vcc |
| 106 | Middle node with analog voltage Van |
| 107 | Chip address register (for storage) |
| 108 | Digitally controllable circuit |
| 109 | Input digital port |
| 110 | Array element |
| 111 | Digital latches or flip-flops |
| 200 | Another embodiment of circuit |
| 201 | A unique device |
| 202 | An alternative to 201 |
| 203 | Wire connection to IC |
| 204 | Circuit generates bits based on device |

### ABBREVIATIONS

A/D Analog-to-Digital
DC Direct current
EEPROM Electrically Erasable Programmable Read-Only Memory
HIC Hybrid Integrated Circuit
ID Identification (Identity)
MIC Monolithic Integrated Circuit
QFN Quad-flat No-leads
T/R Transmit and Receive
Van Voltage analog

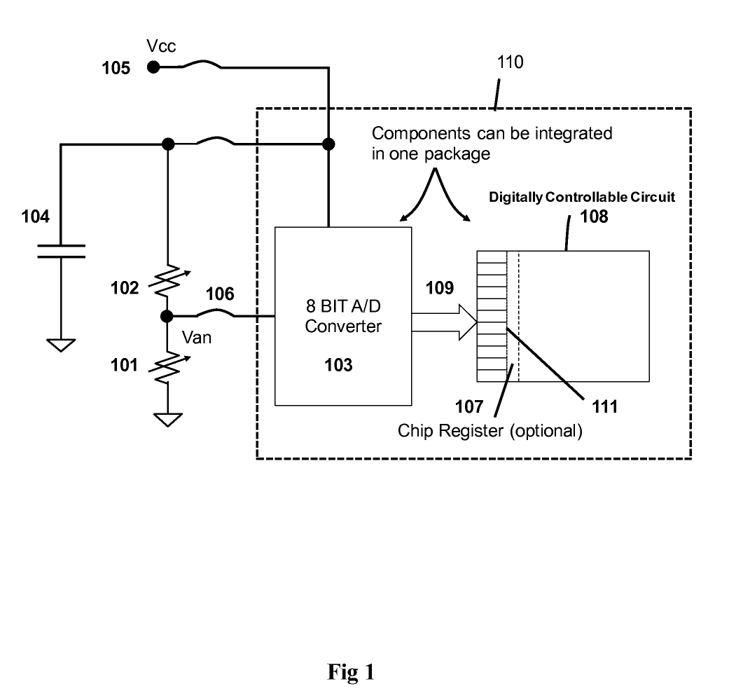

### DETAILED DESCRIPTION—FIG. 1

FIG. 1 is a partial block diagram that shows one embodiment of an arrangement for generating a unique digital word for a digitally controllable circuit. A digitally controllable circuit 108 has parameters, such as frequency, power level, address, and/or any other performance matrix, that are controlled by a digital input at a digital input port 109. Such digitally controllable circuits are used in many applications, including but not limited to array elements of phased-array radars and can also be a single chip or a T/R module.

A supply voltage 105 (Vcc) supplies power for the circuit. A capacitor 104 is used to further stabilize the supply voltage. The supply voltage is fed to the top of a resistor chain comprising variable precision discrete resistors 101 and 102, thereby generating an analog voltage 106 (Van).

Voltage Van is fed to an Analog-to-Digital (A/D) converter 103. Converter 103 converts the analog voltage to a digital bit stream that is equivalent to its digital value. Typically A/D converters are made by bank of comparators elements (refer to The Art of Electronics, by P. Horowitz and W. Hill, Second Edition, Cambridge Press, 1989 pg 612-629). If the level is beyond a certain threshold a bit “1” is generated. For multiple bits, a number of comparisons are done with different levels generating a multiple bit word. The number of bits generated depends upon the number of comparison. In the preferred embodiment the A/D conversion results in eight bits but in general there can be any number of bits.

The digital bits may be stored in a digital buffer 111 composed of an array of digital latches (or flip-flops) in a chip register 107, which is part of circuit 108. Digital latches typically include a feedback circuit and are well known. This digital latch can be used for a number of purposes, including but not limited to controlling digitally controlled circuit 108 or using it as the digital address for the unit. Thus, by choosing the right values for discrete resistors 101 and 102, a prescribed value can be generated for Van, resulting in a prescribed digital word which is usable for controlling the digitally controllable circuit. Typically discrete resistors 101 and 102 are mounted on a surface of a printed-circuit broad and can attached using epoxy or solder.

Due to cost, it is advantageous to form all of the components shown in a single integrated circuit. A/D circuit 103 and digitally controllable circuit 108 can be integrated together to form a single package 110, either on same silicon chip (MIC) or as separate components packaged together (Hybrid IC). Such a part is usually packaged in a plastic package, including but not limited to a quad-flat no-lead (QFN) package. (See for example http://en.wikipedia.org/wiki/Quad-flat_no-leads_package). Thus a low-cost option is to have a single QFN and two external resistors.

### OPERATION—FIG. 1

To understand how the circuit works consider Vcc to be 3.1V. Further assume that the value for resistor 101 is 200 kilo-ohms (200 k) and resistor 102 is 101 k. Thus voltage Van is (3.1×200)/(101+200)=2V. In A/D converter 103 the 3.1 V is subdivided into 2⁸−1 divisions or 255 divisions. Each division is thus (3.1/255) V in size. The first division goes from 0 to 12.157 mV, the second division from 12.157 mV to 24.314 mV, and so on. The 165^{th} division goes from 1.993725 V to 2.005882 V. Since Van is 2 volts and it falls in 165^{th} division, the A/D converter's output 165 in 8-bits, as well as the generated digital word from 2V, is [10100101]. This may be stored in chip register 108 and becomes the digital word to be used by the chip. By changing either or both of resistors 101 and 102 to vary Van, differing address can be generated. Thus each chip can be uniquely programmed or have a unique digital word based on the values of resistors 101 and 102.

In a phased array, the array elements can now be accessed individually as each has a unique address. The digital lines will first send a header containing the address followed by the command to set array element to its right state or configuration. The array element (or the chip) would logically combine or “AND” the header and stored address bit-by-bit. When the result is a “1” it accept the digital command; it will not accept it at any other time. Thus, the same digital line will be able to control any of the array elements.

Due to noise and resistance value inaccuracies, the number of bits that can be created from one set of resistors is limited. Typically, an eight-bit resolution can be achieved with high precision resistors and A/D converters; however, this can only address 64 elements. To address a greater number of elements multiple sets of resistors (like the set comprising resistors 101 and 102), multiple A/D converters, and multiple chip address registers can be connected in parallel. Each set of resistors can provide a unique eight-bit resolution. Thus we can provide the first two resistors to generate an eight-bit address and then next two generate another eight-bit address, and thereby providing sixteen bits or 64×64=65536 bits of addressing capability.

While the exact value of supply voltage, Vcc, is not important, it is important to use the same Vcc for the resistive ladder(s) and for the A/D converter(s). Since the A/D subdivides the Vcc range into subdivisions, each subdivision is proportional to Vcc. Similarly Van is also proportional to Vcc. Thus a change in Vcc does not change the digital word.

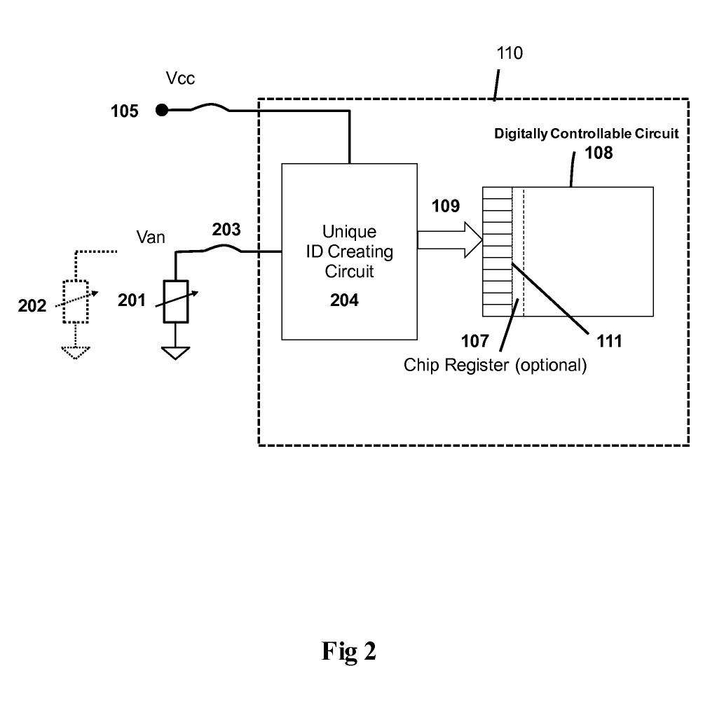

### DETAILED DESCRIPTION—FIG 2

FIG. 2 shows another embodiment in which a unique identity-creating (ID-creating) circuit 204 is connected to chip address register 107, which is part of circuit 108. The ID-creating circuit is connected to a multitude of secondary components 201 and 202. Components 201 and 201 are shown as resistors, but can alternatively be diodes, capacitors, MOS (metal-oxide-semiconductor) transistors, BJTs (bipolar junction transistors) and/or inductors. Although only two components are shown, a greater number can be used. The secondary components have values that are uniquely determined. For example the resistors may have a unique resistance value. Based on selected value, the ID-creating circuit generates a unique digital word comprised of bits and that can form a unique address and may be stored in chip address register 107. Alternatively the generated unique digital word can also be used for controlling digitally controllable circuit 108.

### OPERATION—FIG. 2

To understand how the circuit works consider that unique ID creating circuit 204 is capacitance meter and unique components 201 and 202 are two different capacitors. Since the capacitance meter would determine the capacitance value of components 201 and 202 based on the value it can generate two unique digital word corresponding to each of the capacitance value. Although just one example of device is cited here, it is possible to use many different types of unique devices with a corresponding unique ID-creating circuit. Further each of the unique components can be a combination of two different components, such as a resistor and a capacitor. Clearly there are a number of possibilities and many well know measurement methods can be used with each of the unique components.

### CONCLUSIONS, RAMIFICATIONS, SCOPE

Thus it is seen that I have provided that a unique digital word can be created by proper choice of external components and used to control a digitally controllable circuit. Accordingly one or more aspects of the present system have the following advantages: A unique address for a chip, circuit or module is provided and made externally by a user-selected inexpensive part. Thus no internal memory or fuses are required to create a unique address for an array element. Since this approach avoids the use of microcontrollers and processors, it is very inexpensive. In a phased array application external resistors can be used to generate local address of the array component, thereby simplifying array programming.

While the above description contains many specificities, these are given by way of example and can be varied. For example, although the preferred embodiment uses two external resistors with voltage as reference, there are alternative ways for doing this. First instead of voltage a current source can be used with external resistors to help in diverting that current and determining a ratio. Although it will likely consume more current, the approach is less prone to noise. Similarly while the preferred approach uses two resistors outside of the chip, it is possible to use only one resistance. With one external component to create the voltage Van, we would need another resistor inside the chip. Since the resistor inside the chip would have lower accuracy, the number of bits would decrease. Thus the concepts can be realized in variety of ways.

Therefore the scope should be determined by the appended claims and their legal equivalents and not by the specifics given.

1. A circuit comprising:
(a) a first circuit means that creates a unique analog signal
(b) a second circuit means that converts said unique analog signal to a unique digital word,
(c) a digitally controllable circuit having a plurality of possible states and an input digital port connected to receive said digital word, the state of said circuit being controllable by said digital input at said digital port,
second circuit being arranged to supply said unique digital word to said input digital port of said digitally controllable circuit,
whereby said digital controllable circuit can be assigned a unique state selected from said plurality of possible states.

2. The circuit of claim 1 wherein said digitally controllable component and said second circuit means are integrated in same package.

3. The circuit of claim 2 wherein said first circuit means is outside of said package.

4. The circuit of claim 3 wherein said package is an array element of a phased array.

5. The circuit of claim 2 wherein said digitally controllable component and said second circuit means are monolithic integrated circuits and said package is a plastic package.

6. The circuit of claim 1, further including a digital storage means for storing said unique digital word.

7. The circuit of claim 6 wherein said digital storage means is a register comprising a plurality of digital latches and flip-flops.

8. The circuit of claim 1 wherein said first circuit means comprises two resistors connected in series between a supply voltage and ground and forming a middle node, whereby said unique analog signal is generated from the voltage at said middle node of said resistors.

9. The circuit of claim 1 wherein said digitally controllable component has a digital buffer for storing digital address of said digitally controllable component, and a means for storing said unique digital word in said digital buffer, thereby assigning a unique address for said circuit.
